(19) United States
(12) Patent Application Publication
(10) Pub. No.: US 2025/0016964 A1
(43) Pub. Date: Jan. 9, 2025

(54) NODE UNIT, ELECTRONIC DEVICE AND IMMERSION COOLING TYPE EQUIPMENT

(71) Applicant: ASUSTeK COMPUTER INC., Taipei City (TW)

(72) Inventors: Yu-Wen Chung, Taipei City (TW); Shun-Wei Yang, Taipei City (TW); Heng-Yu Lee, Taipei City (TW); Hao-Yuan Cheng, Taipei City (TW); Chun-Shi Liu, Taipei City (TW); Chia-Wei Chang, Taipei City (TW)

(73) Assignee: ASUSTeK COMPUTER INC., Taipei City (TW)

(21) Appl. No.: 18/459,425

(22) Filed: Sep. 1, 2023

(30) Foreign Application Priority Data
Jul. 6, 2023 (TW) 112125350

(51) Int. Cl. H05K 7/20

(52) U.S. Cl. CPC H05K 7/20772; H05K 7/20236

(57) ABSTRACT

A node unit includes a base plate, at least one function module, and a non-conductive coolant. The function module includes a heat-generating element, a heat-dissipating structure, and a pump. The heat-generating element is disposed on the base plate, the heat-dissipating structure is disposed on the heat-generating element, and the pump is disposed on the heat-dissipating structure. The base plate and the at least one function module are immersed in the non-conductive coolant. The pump is configured to drive the non-conductive coolant to flow into the heat-dissipating structure and discharge from the heat-dissipating structure. An electronic device and an immersion cooling type equipment are also mentioned.

### CROSS-REFERENCE TO RELATED APPLICATION

This application claims the priority benefit of Taiwan application serial no. 112125350, filed on Jul. 6, 2023. The entirety of the above-mentioned patent application is hereby incorporated by reference herein and made a part of this specification.

### BACKGROUND

### Technical Field

The disclosure relates to an electronic equipment and a node unit and an electronic device thereof, and more particularly, to an immersion cooling type equipment and a node unit and an electronic device thereof.

### Description of Related Art

In conventional immersion cooling type server equipment, a pump-driven equipment located below the equipment circulates a cooling liquid to flow through the heat-generating element (e.g., the central processing unit) of the servers, facilitating heat exchange. The cooling liquid then circulates outside the equipment to cool down before being recirculated back into the equipment for further heat exchange. However, if the server has multiple adjacent heat-generating elements, the heat between these heat-generating elements tends to transfer to each other, and the flow efficiency of the cooling liquid between the heat-generating elements is reduced, resulting in decreased cooling effectiveness.

### SUMMARY

The disclosure provides a node unit, an electronic device, and an immersion cooling type equipment with good heat dissipation effect.

The node unit of the disclosure includes a base plate, at least one function module, and a non-conductive coolant. The function module includes a heat-generating element, a heat-dissipating structure, and a pump. The heat-generating element is disposed on the base plate, the heat-dissipating structure is disposed on the heat-generating element, and the pump is disposed on the heat-dissipating structure. The base plate and the at least one function module are immersed in the non-conductive coolant. The pump is configured to drive the non-conductive coolant to flow into the heat-dissipating structure and discharge from the heat-dissipating structure.

The electronic device of the disclosure includes a device body, at least one node unit, and one a non-conductive coolant. The node unit is disposed on the device body and includes a base plate and at least one function module. The at least one function module includes a heat-generating element, a heat-dissipating structure, and a pump. The heat-generating element is disposed on the base plate, the heat-dissipating structure is disposed on the heat-generating element, and the pump is disposed on the heat-dissipating structure. The device body and the at least one node unit are immersed in the non-conductive coolant. The pump is configured to drive the non-conductive coolant to flow into the heat-dissipating structure and discharge from the heat-dissipating structure.

The immersion cooling type equipment of the disclosure includes a tank, an electronic device, and a non-conductive coolant. The electronic device is disposed in the tank and includes a device body and at least one node unit. The at least one node unit is disposed on the device body and have a base plate and at least one function module. The at least one function module includes a heat-generating element, a heat-dissipating structure, and a pump. The heat-generating element is disposed on the base plate, the heat-dissipating structure is disposed on the heat-generating element, and the pump is disposed on the heat-dissipating structure. The non-conductive coolant is accommodated in the tank. The electronic device is immersed in the non-conductive coolant. The pump is configured to drive the non-conductive coolant to flow into the heat-dissipating structure and discharge from the heat-dissipating structure.

Based on the above, the node unit of the disclosure uses the pump to drive the non-conductive coolant to flow into the heat-dissipating structure disposed on the heat-generating element, so that the heat-generating element and the non-conductive coolant may be effectively heat exchanged actively. This design of the node unit provides effective heat dissipation for the heat-generating element. Moreover, since the pump is directly disposed on the heat-dissipating structure rather than being disposed away from the heat-dissipating structure, there is no need for additional pipelines connecting the pump to the heat-dissipating structure. Furthermore, the pump only requires a small amount of power to drive the non-conductive coolant to the heat-dissipating structure, thereby saving equipment costs.

### BRIEF DESCRIPTION OF THE DRAWINGS

FIG. 1 is a schematic view of an immersion cooling type equipment according to an embodiment of the disclosure.

FIG. 2A is a schematic view of a node unit in FIG. 1.

FIG. 2B is a cross-sectional schematic view of the node unit in FIG. 2A along a line I-I.

FIG. 3 is a schematic view of a node unit according to another embodiment of the disclosure.

### DESCRIPTION OF THE EMBODIMENTS

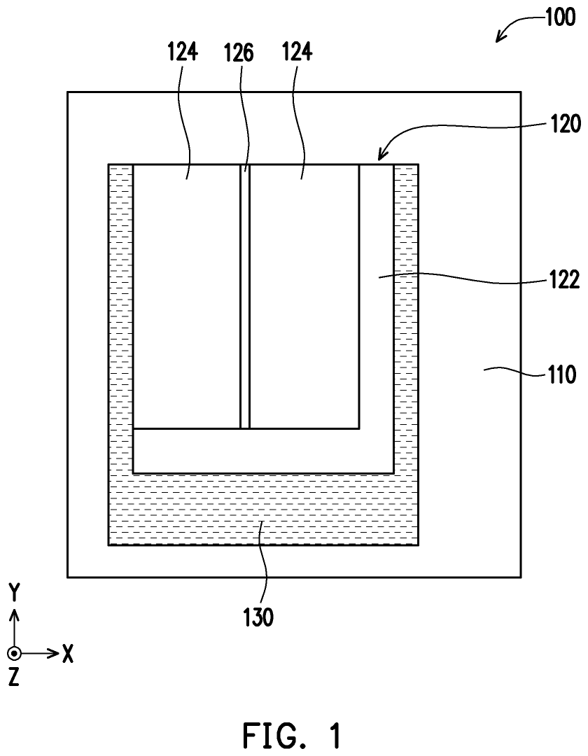

Referring to FIG. 1, an immersion cooling type equipment 100 provided in the disclosure includes a tank 110, an electronic device 120, and a non-conductive coolant 130. The electronic device 120 is, for example, a server, which is disposed in the tank 110 and includes a device body 122 and at least one node unit 124. The node unit 124 is disposed in the device body 122. The non-conductive coolant 130 is accommodated in the tank 110. The electronic device 120 and the device body 122 and the node unit 124 thereof are immersed in the non-conductive coolant 130 to dissipate heat through the non-conductive coolant 130.

After the non-conductive coolant 130 absorbs the heat of the electronic device 120 in the tank 110, the non-conductive coolant 130 circulates to a heat exchange equipment outside the tank 110 for heat exchange to cool down, and then circulates back into the tank 110 to continuously dissipate heat from the electronic device 120.

In one embodiment, the amount of the node unit 124 is, for example, two, but the amount of the node unit 124 is not limited thereto. Moreover, the non-conductive coolant 130 may be mineral oil, fluorinated liquid, synthetic oil, or other suitable non-conductive coolant, and the disclosure is not limited thereto.

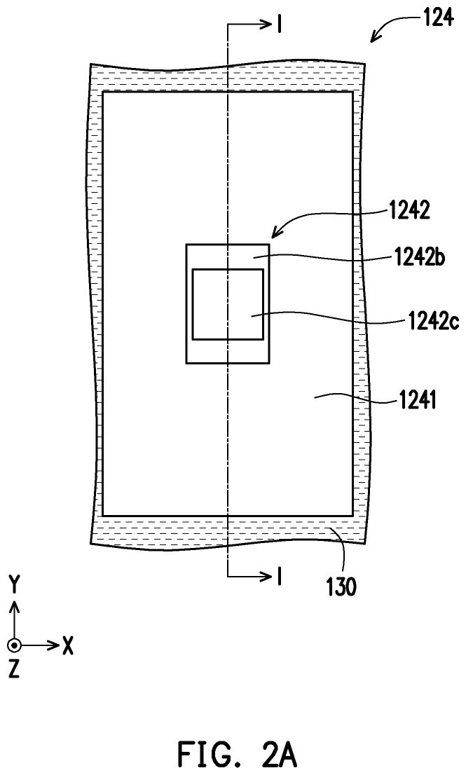

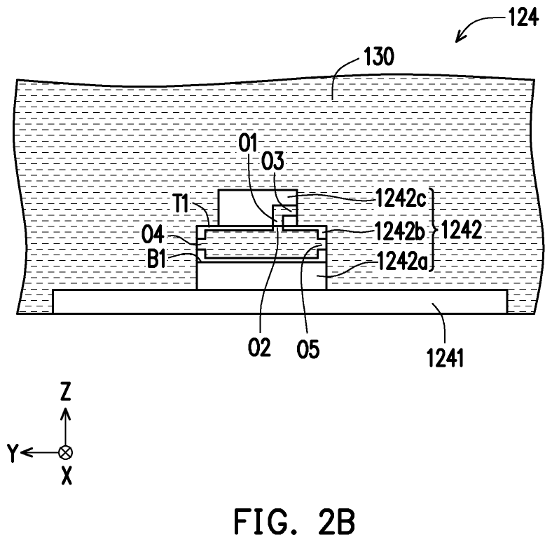

Referring to FIG. 2A and FIG. 2B, the node unit 124 provided in the disclosure includes a base plate 1241, a function module 1242, and a non-conductive coolant 130. The function module 1242 includes a heat-generating element 1242a, a heat-dissipating structure 1242b, and a pump 1242c. The heat-generating element 1242a is disposed on the base plate 1241, the heat-dissipating structure 1242b is disposed on the heat-generating element 1242a, and the pump 1242c is disposed on the heat-dissipating structure 1242b. The base plate 1241 and the function module 1242 are immersed in the non-conductive coolant 130. The pump 1242c is configured to drive the non-conductive coolant 130 to flow into the heat-dissipating structure 1242b and discharge from the heat-dissipating structure 1242b.

As mentioned above, the node unit 124 of the disclosure uses the pump 1242c to drive the non-conductive coolant 130 to flow into the heat-dissipating structure 1242b disposed on the heat-generating element 1242a, so that the heat-generating element 1242a and the non-conductive coolant 130 may be effectively heat exchanged actively. This design of the node unit 124 provides effective heat dissipation for the heat-generating element 1242a.

Since the pump 1242c is directly disposed on the heat-dissipating structure 1242b rather than being disposed away from the heat-dissipating structure 1242b, there is no need for additional pipelines connecting the pump 1242c to the heat-dissipating structure 1242b. Furthermore, the pump 1242c only requires a small amount of power to drive the non-conductive coolant 130 to the heat-dissipating structure 1242b, thereby saving equipment costs.

In one embodiment, the heat-generating element 1242a is, for example, a central processing unit (CPU), and the heat-dissipating structure 1242b is, for example, a cooling plate, but the types of the heat-generating element 1242a and the heat-dissipating structure 1242b are not limited thereto. For example, in other embodiments, the heat-generating element 1242a may be other types of electronic components, and the heat-dissipating structure 1242b may be a heat dissipation fin set.

Referring to FIG. 2B, the heat-dissipating structure 1242b in this embodiment has a top surface T1 and a bottom surface B1 opposite to each other, the bottom surface B1 contacts the heat-generating element 1242a, and the pump 1242c is disposed on the top surface T1. In addition, the pump 1242c has a first opening O1 and a third opening O3. The heat-dissipating structure 1242b has a second opening O2, a fourth opening O4, and a fifth opening O5. The first opening O1 is connected to the second opening O2. The non-conductive coolant 130 is adapted to flow from the pump 1242c into the heat-dissipating structure 1242b through the first opening O1 and the second opening O2 driven by the pump 1242c.

That is, the non-conductive coolant 130 flows into the pump 1242c from the third opening O3 and flows out of the pump 1242c through the first opening O1. In addition, the non-conductive coolant 130 flows into the heat-dissipating structure 1242b through the second opening O2 and the fifth opening O5, and finally flows out of the heat-dissipating structure 1242b through the fourth opening O4.

As shown in FIG. 1, the electronic device 120 in this embodiment further includes a partition plate 126. The partition plate 126 is disposed between two node units 124. Such a design may prevent the flow field of the non-conductive coolant 130 of the two node units 124 from influencing each other, so as to achieve the expected heat dissipation effect.

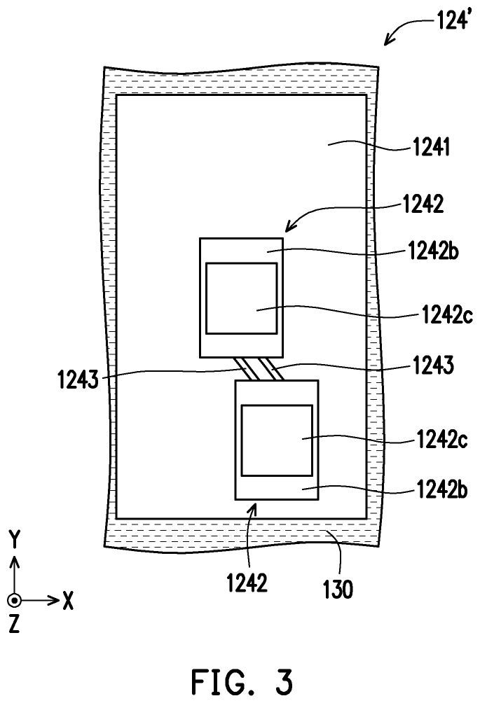

FIG. 3 is a schematic view of a node unit according to another embodiment of the disclosure. The difference between the embodiment shown in FIG. 3 and the aforementioned embodiment is that the amount of the function module 1242 of the node unit 124′ in FIG. 3 is two. In addition, the node unit 124′ further includes at least one pipe 1243. The pipe 1243 is connected between the heat-dissipating structures 1242b of the two function modules 1242. In this embodiment, the amount of the pipe 1243 is, for example, two, but the amount of the pipe 1243 is not limited thereto.

By disposing of the pipe 1243 between the heat-dissipating structures 1242b of the two function modules 1242, the two heat-dissipating structures 1242b may communicate with each other. That is, the non-conductive coolant 130 flows from the fourth opening O4 (FIG. 2B) of one of the heat-dissipating structure 1242b to the fifth opening O5 (FIG. 2B) of another heat-dissipating structure 1242b through the pipe 1243. Thus, each pump 1242c has the ability to drive the non-conductive coolant 130 to flow in the two heat-dissipating structures 1242b. Accordingly, even if any one of the two pumps 1242c fails, the remaining pump 1242c may continue to drive the non-conductive coolant 130 to flow in the two heat-dissipating structures 1242b.

To sum up, the node unit of the disclosure uses the pump to drive the non-conductive coolant to flow into the heat-dissipating structure disposed on the heat-generating element, so that the heat-generating element and the non-conductive coolant may be effectively heat exchanged actively. This design of the node unit provides effective heat dissipation for the heat-generating element. Moreover, since the pump is directly disposed on the heat-dissipating structure rather than being disposed away from the heat-dissipating structure, there is no need for additional pipelines connecting the pump to the heat-dissipating structure. Furthermore, the pump only requires a small amount of power to drive the non-conductive coolant to the heat-dissipating structure, thereby saving equipment costs. In addition, the design uses a pipe disposed between the heat-dissipating structures of the two function modules to ensure that when one of the pumps of the two function modules fails, the other pump may continuously supply the non-conductive coolant to the two heat-dissipating structures, thereby ensuring continuous heat exchange between the non-conductive coolant and the heat-generating element. Furthermore, by disposing of the partition plate between the two node units, the flow field of the non-conductive coolant of the two node units in the electronic device is isolated, thereby achieving effective heat dissipation.

What is claimed is:

1. A node unit, comprising:
a base plate;
at least one function module, comprising;
a heat-generating element, a heat-dissipating structure, and a pump, wherein the heat-generating element is disposed on the base plate, the heat-dissipating structure is disposed on the heat-generating element, and the pump is disposed on the heat-dissipating structure; and
a non-conductive coolant, in which the base plate and the at least one function module are immersed, wherein the pump is configured to drive the non-conductive coolant to flow into the heat-dissipating structure and discharge from the heat-dissipating structure.

2. The node unit according to claim 1, wherein the heat-dissipating structure has a top surface and a bottom surface opposite to each other, the bottom surface contacts the heat-generating element, and the pump is disposed on the top surface.

3. The node unit according to claim 1, wherein the pump has a first opening, the heat-dissipating structure has a second opening, the first opening is connected to the second opening, and the non-conductive coolant is adapted for flowing from the pump into the heat-dissipating structure through the first opening and the second opening.

4. The node unit according to claim 1, further comprising at least one pipe, wherein an amount of the at least one function module is two, and the at least one pipe is connected to the heat-dissipating structure of one function module and the heat-dissipating structure of another function module.

5. The node unit according to claim 1, wherein the heat-dissipating structure is a cooling plate or a heat dissipation fin set.

6. The node unit according to claim 1, wherein the heat-generating element is a processor.

7. An electronic device, comprising:
a device body;
at least one node unit, disposed on the device body and have a base plate and at least one function module, wherein the at least one function module comprises a heat-generating element, a heat-dissipating structure, and a pump, the heat-generating element is disposed on the base plate, the heat-dissipating structure is disposed on the heat-generating element, and the pump is disposed on the heat-dissipating structure; and
a non-conductive coolant, in which the device body and the at least one node unit are immersed, wherein the pump is configured to drive the non-conductive coolant to flow into the heat-dissipating structure and discharge from the heat-dissipating structure.

8. The electronic device according to claim 7, wherein the heat-dissipating structure has a top surface and a bottom surface opposite to each other, the bottom surface contacts the heat-generating element, and the pump is disposed on the top surface.

9. The electronic device according to claim 7, wherein the pump has a first opening, the heat-dissipating structure has a second opening, the first opening is connected to the second opening, and the non-conductive coolant is adapted for flowing from the pump into the heat-dissipating structure through the first opening and the second opening.

10. The electronic device according to claim 7, wherein the heat-dissipating structure is a cooling plate or a heat dissipation fin set.

11. The electronic device according to claim 7, wherein the heat-generating element is a processor, and the electronic device is a server.

12. The electronic device according to claim 7, wherein the at least one node unit further comprises at least one pipe, an amount of the at least one function module is two, and the at least one pipe is connected to the heat-dissipating structure of one function module and the heat-dissipating structure of another function module.

13. The electronic device according to claim 7, further comprising: a partition plate, wherein an amount of the at least one node unit is two, and the partition plate is disposed between the two node units.

14. An immersion cooling type equipment, comprising:
a tank;
an electronic device, disposed in the tank and comprising:
a device body; and
at least one node unit, disposed on the device body and have a base plate and at least one function module, wherein the at least one function module comprises a heat-generating element, a heat-dissipating structure, and a pump, the heat-generating element is disposed on the base plate, the heat-dissipating structure is disposed on the heat-generating element, and the pump is disposed on the heat-dissipating structure; and
a non-conductive coolant, accommodated in the tank, wherein the electronic device is immersed in the non-conductive coolant, and the pump is configured to drive the non-conductive coolant to flow into the heat-dissipating structure and discharge from the heat-dissipating structure.

15. The immersion cooling type equipment according to claim 14, wherein the heat-dissipating structure has a top surface and a bottom surface opposite to each other, the bottom surface contacts the heat-generating element, and the pump is disposed on the top surface.

16. The immersion cooling type equipment according to claim 14, wherein the pump has a first opening, the heat-dissipating structure has a second opening, the first opening is connected to the second opening, and the non-conductive coolant is adapted for flowing from the pump into the heat-dissipating structure through the first opening and the second opening.

17. The immersion cooling type equipment according to claim 14, wherein the heat-dissipating structure is a cooling plate or a heat dissipation fin set.

18. The immersion cooling type equipment according to claim 14, wherein the heat-generating element is a processor, and the electronic device is a server.

19. The immersion cooling type equipment according to claim 14, wherein the at least one node unit further comprises at least one pipe, an amount of the at least one function module is two, and the at least one pipe is connected to the heat-dissipating structure of one function module and the heat-dissipating structure of another function module.

20. The immersion cooling type equipment according to claim 14, wherein the electronic device further comprises a partition plate, an amount of the at least one node unit is two, and the partition plate is disposed between the two node units.
